(19) United States
(12) Patent Application Publication
(10) Pub. No.: US 2021/0287924 A1
(43) Pub. Date: Sep. 16, 2021

(54) SEMICONDUCTOR SUBSTRATE SUPPORT WITH WAFER BACKSIDE DAMAGE CONTROL

(71) Applicant: Applied Materials, Inc,, Santa Clara, CA (US)

(72) Inventors: Jian Li, Fremont, CA (US); Paul L. Brillhart, Pleasanton, CA (US); Juan Carlos Rocha-Alvarez, San Carlos, CA (US); Abdul Aziz Khaja, San Jose, CA (US); Vinay K. Prabhakar, Cupertino, CA (US); Kwangduk Douglas Lee, Redwood City, CA (US); Chidambara A. Ramalingam, Fremont, CA (US); Venkata Sharat Chandra Parimi, Sunnyvale, CA (US)

(73) Assignee: Applied Materials, Inc., Santa Clara, CA (US)

(21) Appl. No.: 16/820,205

(22) Filed: Mar. 16, 2020

(51) Int. Cl. H01L 21/683; H01L 21/324; H01L 21/67; H01J 37/32; C23C 16/50; C23C 16/458; C23C 16/46

(52) U.S. Cl. CPC H01L 21/6833; H01L 21/324; H01L 21/67103; H01J 2237/332; C23C 16/50; C23C 16/4586; C23C 16/46; H01J 37/32724

(57) ABSTRACT

Exemplary support assemblies may include an electrostatic chuck body defining a substrate support surface. The substrate support assemblies may include a support stem coupled with the electrostatic chuck body. The substrate support assemblies may include a heater embedded within the electrostatic chuck body. The substrate support assemblies may include an electrode embedded within the electrostatic chuck body between the heater and the substrate support surface. The substrate support assembly may include a ceramic material characterized by a grain size of less than or about 5 μm.

### TECHNICAL FIELD

The present technology relates to components and apparatuses for semiconductor manufacturing. More specifically, the present technology relates to substrate support assemblies and other semiconductor processing equipment.

### BACKGROUND

Integrated circuits are made possible by processes which produce intricately patterned material layers on substrate surfaces. Producing patterned material on a substrate requires controlled methods for forming and removing material. The temperature at which these processes occur may directly impact the final product. Substrate temperatures are often controlled and maintained with the assembly supporting the substrate during processing. Internally located heating devices may generate heat within the support, and the heat may be transferred conductively to the substrate. The substrate support may also be utilized in some technologies to develop a substrate-level plasma.

As a variety of operational processes may utilize increased temperature to produce a series of high stress films, increased clamping voltages may be utilized that may increase effects on the substrate. Thus, there is a need for improved systems and methods that can be used to produce high quality devices and structures. These and other needs are addressed by the present technology.

### SUMMARY

Exemplary substrate support assemblies may include an electrostatic chuck body defining a substrate support surface. The substrate support assemblies may include a support stem coupled with the electrostatic chuck body. The substrate support assemblies may include a heater embedded within the electrostatic chuck body. The substrate support assemblies may include an electrode embedded within the electrostatic chuck body between the heater and the substrate support surface. The substrate support assembly may include a ceramic material characterized by a grain size of less than or about 5 μm.

In some embodiments, the electrostatic chuck body may define a recessed pocket along the substrate support surface encompassing a central region of the electrostatic chuck body. The substrate support surface may define a recessed ledge extending radially inward from an outer radial edge of the recessed pocket. The electrostatic chuck body may define a plurality of protrusions extending from the substrate support surface within the recessed pocket. Each protrusion of the plurality of protrusions may be characterized by a rounded corner profile characterized by a corner radius of at least 10% of a height of each protrusion. The electrostatic chuck body may define greater than or about 500 protrusions, and each protrusion of the plurality of protrusions may be characterized by a diameter of greater than or about 1 mm. A subset of protrusions of the plurality of protrusions may be characterized by a diameter of greater than or about 2 mm. The plurality of protrusions may define a contact area for a substrate seated on the substrate support surface of the electrostatic chuck body, and the contact area may be less than or about 10% of a planar area of the substrate. The ceramic material may be characterized by a grain size of between about 1 μm and about 3 μm. The ceramic material may be or include aluminum nitride. The ceramic material may be characterized by a surface roughness arithmetical mean height of less than or about 0.5 μm. The ceramic material may be characterized by a surface roughness maximum peak height of less than or about 2 μm.

Some embodiments of the present technology may encompass substrate support assemblies including a first electrostatic chuck body defining a substrate support surface. The substrate support assemblies may include a second electrostatic chuck body defining a bulk chuck body. The substrate support assemblies may include a support stem coupled with the second electrostatic chuck body. The substrate support assemblies may include a heater embedded within the second electrostatic chuck body. The substrate support assemblies may include an electrode embedded within the second electrostatic chuck body between the heater and the first electrostatic chuck body. The first electrostatic chuck body may be or include a ceramic material characterized by an average grain size of less than or about 5 μm.

In some embodiments, the second electrostatic chuck body may be or include a ceramic material characterized by an average grain size of greater than or about 3 μm. The first electrostatic chuck body may be or include aluminum nitride, and the second electrostatic chuck body may be or include aluminum nitride. The first electrostatic chuck body may define a recessed pocket within the substrate support surface configured to receive a substrate for processing. The substrate support surface may define a recessed ledge extending radially inward from an outer radial edge of the recessed pocket. The first electrostatic chuck body may define a plurality of protrusions extending from the substrate support surface within the recessed pocket. The plurality of protrusions may define a contact area for a substrate seated on the substrate support surface of the first electrostatic chuck body. The contact area may be less than or about 5% of a planar area of the substrate. The first electrostatic chuck body may be characterized by a surface roughness arithmetical mean height of less than or about 0.5 μm.

Some embodiments of the present technology may encompass methods of processing a semiconductor substrate. The methods may include clamping a semiconductor substrate to a substrate support with a chucking voltage of greater than or about −300 V. The methods may include heating a substrate to a processing temperature causing thermal expansion of the semiconductor substrate. The methods may include de-clamping the semiconductor substrate. Scratches formed on a backside of the semiconductor substrate may be limited to a width of less than or about 2 μm or less.

Such technology may provide numerous benefits over conventional systems and techniques. For example, embodiments of the present technology may provide substrate supports that may reduce or limit substrate backside damage during semiconductor processing. This may contribute to reduced backside fall-on particles as well as improved processing operations that may happen subsequently, such as lithographic operations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a method of processing a semiconductor substrate according to some embodiments of the present technology.

FIG. 3 shows a schematic partial cross-sectional view of an exemplary substrate support assembly according to some embodiments of the present technology.

FIG. 4 shows a schematic partial cross-sectional view of an exemplary substrate support assembly according to some embodiments of the present technology.

FIG. 5 shows a schematic partial cross-sectional view of an exemplary substrate support assembly according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. These formed films may be produced under conditions that cause stresses on the substrate. For example, in the development of dielectric layers for vertical memory applications, such as ON stacks, many layers of material may be deposited on a substrate. These produced films may be characterized by internal stresses that act upon the substrate. This may cause a substrate to bow during processing, which can lead to poor uniformity of formation, as well as device damage or malfunction.

An electrostatic chuck may be used to produce a clamping action against the substrate to overcome the bowing stress. However, as these device stacks increase in numbers of layers, the stresses acted upon the substrate increase, which may require a proportional increase in chucking voltage. Additionally, many of these films may be developed at relatively high temperatures that further affect components of the chamber. For example, some deposition activities may occur at temperatures above 500° C. or higher, which may cause the substrate to thermally expand outward radially. The expansion in combination with the increased chucking voltage may cause scratches to be formed on the backside of a semiconductor substrate in contact with the substrate support.

These scratches may cause multiple challenges. For example, when a substrate is removed from processing and replaced in a front-opening unified pod with other processed substrates, particles generated from the scratches may fall to underlying substrates, which may act as defects in the produced films for the underlying substrates. Additionally, some subsequent processing may be affected by the damage. For example, subsequent operations may include lithography, such as hard mask lithography. Backside damage may cause displacement of the projected beam through the substrate, which may affect the lithography process. These issues have limited conventional technologies and caused loss of wafers due to the impact on subsequent processing. The present technology overcomes these challenges with substrate support assemblies having particular materials and configurations exhibiting grain sizes, specific roughness characteristics, as well as physical characteristics that may limit substrate backside damage, especially at increased temperatures.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may include substrate support assemblies according to embodiments of the present technology before additional variations and adjustments to this system according to embodiments of the present technology are described.

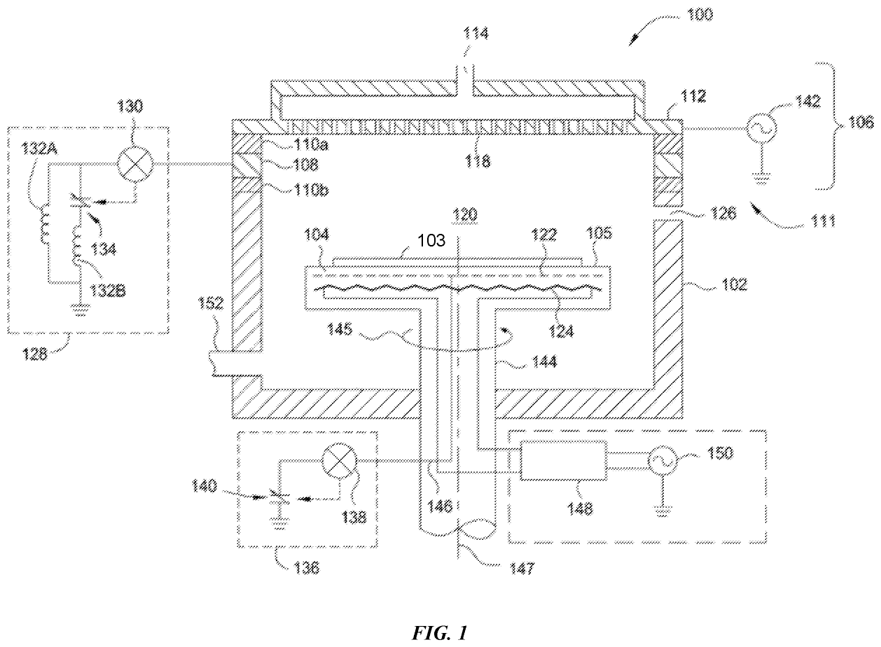

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

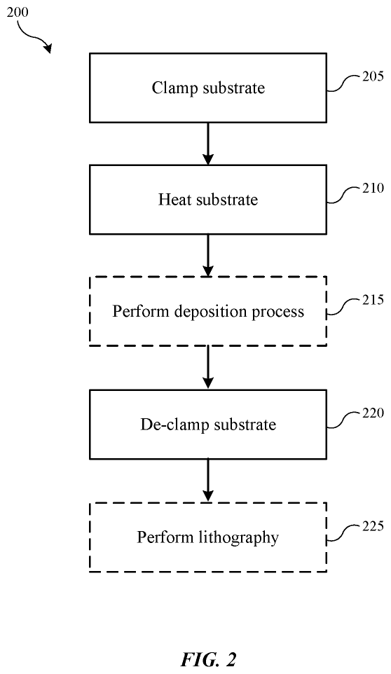

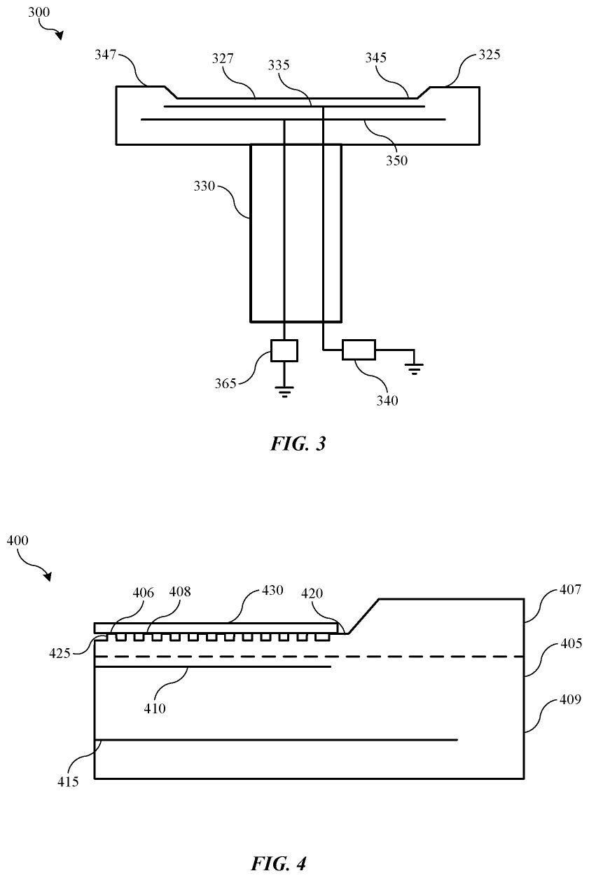

FIG. 2 shows exemplary operations in a processing method 200 according to some embodiments of the present technology. The method may be performed in a variety of processing chambers, including processing system 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations performed with substrate support assemblies shown schematically in FIGS. 3-4, the illustrations of which will be described in conjunction with the operations of method 200. It is to be understood that the figures illustrate only partial schematic views, and a substrate support assembly may contain any number of additional materials and features having a variety of characteristics and aspects as illustrated in the figures.

As discussed previously, the present technology may encompass substrate supports characterized by improved surface characteristics compared to conventional technologies. By producing substrate supports, or portions of substrate supports, that provide a smoother surface to substrates, backside damage caused upon the substrate may be reduced. For example, in exemplary method 200, a substrate may be provided to a processing chamber for deposition. In one non-limiting example, the process may involve forming a number of layers of material on a surface of a substrate. For memory stacks, such as ON stacks, this can be dozens of layers of material or more. Many of these materials may be characterized by internal stresses that act upon the substrate. These materials may be formed as pairs of layers, and as the number of pairs of layers increases, the forces acting on the substrate may increase. Higher temperatures may contribute to these forces, further increasing the amount of bowing, and challenging the capability to properly chuck the substrate to the support assembly. To compensate for these forces, an increased chucking voltage may be used to maintain a substantially planar substrate surface, although an amount of bowing may still occur. As these layer pairs continue to increase, the minimum voltage to maintain chucking may continue to increase.

Although smart chucking or ramped chucking may be performed, such as to increase the voltage during processing as the stresses acting upon the substrate increase from further deposition, many processes may simply clamp the substrate at a predetermined voltage sufficient to compensate or overcome the stresses likely to be enacted on the substrate during the processing. However, when the substrate is seated on the substrate support and electrostatically clamped, the substrate may not have reached processing temperatures, and may be well below a temperature at which processing is to occur. As the substrate acclimates and increases in temperature, the substrate may thermally expand causing an outward radial expansion of the wafer. The clamping enacted on the substrate may essentially pull the substrate into the surface, which may be characterized by the exposed grain structure of the support. High clamping voltages may cause impact on the backside of the substrate. As the wafer expands while remaining clamped, the grains impinging on the backside of the wafer may score the wafer during the outward expansion. This may be at least partially unavoidable in some processing in order to ensure adequate clamping to overcome processing stresses on the substrate.

The present technology may improve the backside damage on substrates by utilizing improved substrate supports that may be characterized by reduced surface roughness. By producing substrate supports characterized by reduced grain sizes, the extent of impingement of the grains on the backside of the wafer may be reduced. Additionally, reduced grain sizes may increase the number of points of contact on the substrate by reducing peak and valley roughness characteristics, which may further distribute the clamping forces on the substrate to more locations about the substrate backside surface. This may cause less damage during thermal expansion, which may reduce particulate material produced by the scratches. Additionally, later processing, such as lithography, may be less impacted by the reduced width of the scratches produced, which may improve subsequent processing of the substrates.

Method 200 may include operations for a substrate seated on one or more substrate supports according to embodiments of the present technology, and characterized by reduced grain size structures. Method 200 may include providing a substrate to a processing chamber in which a substrate support according to embodiments of the present technology may be included, such as chamber 100 described above. The substrate may be deposited on the substrate support, and may be electrostatically clamped to the substrate support at operation 205, which may include any clamping voltage as further described below. The substrate may be pre-heated before being deposited on the substrate support, although in some embodiments the substrate may be at a temperature below a processing temperature and/or below a substrate support temperature. The substrate may be heated by the substrate support at operation 210, which may occur subsequent the clamping, and may cause thermal expansion of the substrate.

One or more processes may be performed while the substrate is positioned within the chamber, such as, for example, one or more deposition operations at optional operation 215. As described above, such as for an exemplary memory stack formation, a number of layers of dielectric materials and/or placeholder materials may be formed overlying the substrate. After processing is complete, the substrate may be de-clamped from the substrate support at operation 220, and removed from the chamber. Additional operations may occur on the same tool, or the substrate may be returned to a front-opening unified pod to be transferred elsewhere. Subsequent processing may occur, and may include any number of operations that may extend through packaging. In one exemplary embodiment, subsequent operations may include a lithographic operation at optional operation 225. For example, during hard mask lithography, the lithographic tool may image through the wafer. Backside scratches may cause lithographic defocus, which may affect device yield. As will be explained below, the present technology may substantially reduce and may resolve lithographic defocus in some embodiments.

FIG. 3 shows a schematic partial cross-sectional view of an exemplary semiconductor substrate support 300 according to some embodiments of the present technology. FIG. 3 may include one or more components discussed above with regard to FIG. 1, and may illustrate further details relating to that chamber. The support 300 may be used during semiconductor processing operations including deposition of stacks of dielectric materials as previously described. Substrate support 300 may show a partial view of components and couplings within an exemplary semiconductor processing system, and may not include all of the components, such as the chamber components and characteristics previously described, which are understood to be incorporated in some embodiments about and with substrate support 300.

The substrate support assembly may include an electrostatic chuck body 325, which may include one or more components embedded or disposed within the body. The components incorporated within the top puck may not be exposed to processing materials in some embodiments, and may be fully retained within the chuck body 325. Electrostatic chuck body 325 may define a substrate support surface 327, and may be characterized by a thickness and length or diameter depending on the specific geometry of the chuck body. In some embodiments the chuck body may be elliptical, and may be characterized by one or more radial dimensions from a central axis through the chuck body. It is to be understood that the top puck may be any geometry, and when radial dimensions are discussed, they may define any length from a central position of the chuck body.

Electrostatic chuck body 325 may be coupled with a stem 330, which may support the chuck body and may include channels as will be discussed below for delivering and receiving electrical and/or fluid lines that may couple with internal components of the chuck body 325. Chuck body 325 may include associated channels or components to operate as an electrostatic chuck, although in some embodiments the assembly may operate as or include components for a vacuum chuck, or any other type of chucking system. Stem 330 may be coupled with the chuck body on a second surface of the chuck body opposite the substrate support surface. The electrostatic chuck body 325 may include an electrode 335, which may be a DC electrode, embedded within the chuck body proximate the substrate support surface. Electrode 335 may be electrically coupled with a power source 340. Power source 340 may be configured to provide energy or voltage to the electrically conductive chuck electrode 335. This may be operated to form a plasma of a precursor within the processing region of the semiconductor processing chamber within which the substrate support assembly is disposed, although other plasma operations may similarly be sustained. For example, electrode 335 may also be a chucking mesh that operates as electrical ground for a capacitive plasma system including an RF source electrically coupled with a showerhead or other chamber component. For example, electrode 335 may operate as a ground path for RF power from the RF source coupled elsewhere in the chamber, while also operating as an electric bias to the substrate to provide electrostatic clamping of the substrate to the substrate support surface. Power source 340 may include a filter, a power supply, and a number of other electrical components configured to provide a chucking voltage.

In operation, a substrate may be in at least partial contact with the substrate support surface of the electrostatic chuck body, which may produce a contact gap, which may essentially produce a capacitive effect between a surface of the pedestal and the substrate. Voltage may be applied to the contact gap, which may generate an electrostatic force for chucking. The power supply 340 may provide electric charge that migrates from the electrode to the substrate support surface where it may accumulate, and which may produce a charge layer having Coulomb attraction with opposite charges at the substrate, and which may electrostatically hold the substrate against the substrate support surface of the chuck body. This charge migration may occur by current flowing through a dielectric material of the chuck body based on a finite resistance within the dielectric for Johnsen-Rahbek type chucking, which may be used in some embodiments of the present technology.

Chuck body 325 may also define a recessed region 345 within the substrate support surface, which may provide a recessed pocket in which a substrate may be disposed. Recessed region 345 may be formed at an interior region of the top puck and may be configured to receive a substrate for processing. Recessed region 345 may encompass a central region of the electrostatic chuck body as illustrated, and may be sized to accommodate any variety of substrate sizes. A substrate may be seated within the recessed region, and contained by an exterior region 347, which may encompass the substrate. In some embodiments the height of exterior region 347 may be such that a substrate is level with or recessed below a surface height of the substrate support surface at exterior region 347. A recessed surface may control edge effects during processing, which may improve uniformity of deposition across the substrate in some embodiments. In some embodiments, an edge ring may be disposed about a periphery of the top puck, and may at least partially define the recess within which a substrate may be seated. In some embodiments, the surface of the chuck body may be substantially planar, and the edge ring may fully define the recess within which the substrate may be seated.

In some embodiments the electrostatic chuck body 325 and/or the stem 330 may be insulative or dielectric materials. For example, oxides, nitrides, carbides, and other materials may be used to form the components. Exemplary materials may include ceramics, including aluminum oxide, aluminum nitride, silicon carbide, tungsten carbide, and any other metal or transition metal oxide, nitride, carbide, boride, or titanate, as well as combinations of these materials and other insulative or dielectric materials. Different grades of ceramic materials may be used to provide composites configured to operate at particular temperature ranges, and thus different ceramic grades of similar materials may be used for the top puck and stem in some embodiments. Dopants may be incorporated in some embodiments to adjust electrical properties as will be explained further below. Exemplary dopant materials may include yttrium, magnesium, silicon, iron, calcium, chromium, sodium, nickel, copper, zinc, or any number of other elements known to be incorporated within a ceramic or dielectric material.

In some embodiments the ceramic materials may be specifically formed or processed to reduce grain size. Although some polishing operations may enable relatively reduced surface roughness, the present technology may incorporate ceramics with reduced grain sizes produced during formation, which may limit surface roughness characteristics. For example, the chuck body may be developed during a sintering process in which particulate material and binder are compressed at high temperature. This may cause the binder to be driven from the body or bodies, and then a glass transition may occur, and grains may form. High temperature may also be used to reduce moisture from the ceramic and limit defect formation, although the higher temperature may increase grain sizes. Accordingly, many substrate support bodies are characterized by grain sizes greater than 5 μm or more. The present technology may perform the sintering at slightly reduced temperatures, such as about 100° C. or more below average sintering temperatures, such as 1800° C. to 2000° C., for example, which may control grain growth. Consequently, chuck bodies according to some embodiments of the present technology may be characterized by average grain sizes of less than or about 5 μm, and may be characterized by average grain sizes of less than or about 4 μm, less than or about 3.5 μm, less than or about 3 μm, less than or about 2.5 μm, less than or about 2 μm, less than or about 1.5 μm, less than or about 1 μm, or less. However, average grain sizes may be maintained at greater than or about 0.5 μm, or greater than or about 1 μm to ensure uniformity of the chuck body characteristics and limit formation defects.

The grain sizes may impact a number of surface roughness characteristics, and chuck bodies according to some embodiments of the present technology may be characterized by reduced roughness aspects. For example, for substrate support chuck bodies characterized by reduced grain sizes according to some embodiments of the present technology, a surface roughness arithmetical mean height may be less than or about 0.7 μm, and may be less than or about 0.65 μm, less than or about 0.60 μm, less than or about 0.55 μm, less than or about 0.50 μm, less than or about 0.45 μm, less than or about 0.40 μm, less than or about 0.35 μm, less than or about 0.30 μm, less than or about 0.25 μm, less than or about 0.20 μm, or less.

A surface roughness maximum peak height may be less than or about 2.5 μm, and may be less than or about 2.0 μm, less than or about 1.75 μm, less than or about 1.50 μm, less than or about 1.40 μm, less than or about 1.30 μm, less than or about 1.25 μm, less than or about 1.20 μm, less than or about 1.15 μm, less than or about 1.10 μm, less than or about 1.05 μm, less than or about 1.00 μm, less than or about 0.95 μm, less than or about 0.90 μm, less than or about 0.85 μm, or less. This may limit the amount of impingement on the backside of the substrate, and may also increase the points of contact across the substrate to better distribute clamping force. Similarly, a surface roughness maximum valley or pit height may be less than or about 3.0 μm, and may be less than or about 2.5 μm, less than or about 2.0 μm, less than or about 1.75 μm, less than or about 1.50 μm, less than or about 1.40 μm, less than or about 1.30 μm, less than or about 1.25 μm, less than or about 1.20 μm, less than or about 1.15 μm, less than or about 1.10 μm, less than or about 1.05 μm, or less. This may limit the extent that clamping may pull the substrate within the grains and limit impingement of grains on the substrate. A surface roughness maximum height, or difference between largest peak height and largest valley depth, may be less than or about 5.0 μm, and may be less than or about 4.5 μm, less than or about 4.0 μm, less than or about 3.5 μm, less than or about 3.0 μm, and may be less than or about 2.5 μm, less than or about 2.0 μm, less than or about 1.75 μm, less than or about 1.50 μm, or less. With chuck bodies having average grain sizes above about 5 μm, this maximum height may be more than 6 μm or more, expanding roughness, and increasing the scratch width on the backside of the wafer.

Consequently, due to the improved roughness characteristics, the present technology may reduce the scratch width on the backside of substrates, and may reduce scratch width to less than or about 2 μm, less than or about 1.75 μm, less than or about 1.50 μm, less than or about 1.25 μm, less than or about 1.00 μm, less than or about 0.90 μm, less than or about 0.80 μm, less than or about 0.70 μm, less than or about 0.60 μm, less than or about 0.50 μm, less than or about 0.40 μm, less than or about 0.30 μm, or less. When subsequent lithography is performed as previously described, the present technology may reduce lithography defocus across the substrate, by producing backside scratches of reduced dimensions as described. Some conventional technologies produced an average lithography defocus number of points across a substrate of greater than or about 0.6 across a set of substrates. The present technology may provide a number of positions of lithography defocus of less than or about 0.3, less than or about 0.2, less than or about 0.1, and some embodiments of the present technology produced zero positions of lithography defocus, fully resolving the defocus issue. Additionally, backside fall-on particles were reduced from over 50, to less than 5 in some embodiments of the present technology.

Electrostatic chuck body 325 may also include an embedded heater 350 contained within the chuck body. Heater 350 may include a resistive heater or a fluid heater in embodiments. In some embodiments the electrode 335 may be operated as the heater, but by decoupling these operations, more individual control may be afforded, and extended heater coverage may be provided while limiting the region for plasma formation. Heater 350 may include a polymer heater bonded or coupled with the chuck body material, although a conductive element may be embedded within the electrostatic chuck body and configured to receive current, such as AC current, to heat the top puck. The current may be delivered through the stem 330 through a similar channel as the DC power discussed above. Heater 350 may be coupled with a power supply 365, which may provide current to a resistive heating element to facilitate heating of the associated chuck body and/or substrate. Heater 350 may include multiple heaters in embodiments, and each heater may be associated with a zone of the chuck body, and thus exemplary chuck bodies may include a similar number or greater number of zones than heaters. The chucking mesh electrode 335 may be positioned between the heater 350 and the substrate support surface 327 in some embodiments, and a distance may be maintained between the electrode within the chuck body and the substrate support surface in some embodiments.

The heater 350 may be capable of adjusting temperatures across the electrostatic chuck body 325, as well as a substrate residing on the substrate support surface 327. The heater may have a range of operating temperatures to heat the chuck body and/or a substrate above or about 100° C., and the heater may be configured to heat above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., above or about 650° C., above or about 700° C., above or about 750° C., above or about 800° C., above or about 850° C., above or about 900° C., above or about 950° C., above or about 1000° C., or higher. The heater may also be configured to operate in any range encompassed between any two of these stated numbers, or smaller ranges encompassed within any of these ranges. In some embodiments, the chuck heater may be operated to maintain a substrate temperature above at least 500° C. during deposition operations, such as forming stacks of material for memory devices as previously described.

FIG. 4 shows a schematic partial cross-sectional view of an exemplary substrate support assembly 400 according to some embodiments of the present technology. Substrate support assembly 400 may include any of the materials or components previously described, and may illustrate additional details of substrate support assemblies previously discussed. As illustrated, an electrostatic chuck body 405 may include an embedded electrode 410 and an embedded heater 415 as previously described. A substrate support surface 406 may be defined by the chuck body and may be configured to support a semiconductor substrate 430. The substrate support surface may define a recessed pocket 408 within the substrate support surface. A recessed ledge 420 may be defined in the substrate support surface as well. The recessed ledge may extend radially inward from an outer radial edge of the recessed pocket. Additionally, the substrate support surface may define a number of protrusions 425 extending from the substrate support surface within the recessed pocket 408. An exposed surface across the protrusions 425 may define contact locations where substrate 430 may contact the substrate support surface.

In some embodiments the chuck body may include multiple bodies characterized by any number of features, grain sizes, and roughness characteristics as previously described. Producing ceramics characterized by reduced grain sizes may impact resistance characteristics, and may increase unit cost of the chuck body. Accordingly, in some embodiments the substrate support may include a first chuck body 407 coupled with a second chuck body 409. For example, while the first chuck body 407 may be characterized by reduced grain sizes as described previously, the second chuck body 409 may be characterized by larger average grain sizes, such as greater than or about 3 μm, greater than or about 4 μm, greater than or about 5 μm, greater than or about 6 μm, greater than or about 7 μm, or more. This may facilitate formation and embedding the heater and electrode, and may improve electrical characteristics of the support. The first chuck body 405 may include the surface in contact with the substrate and the defined protrusions and pocket. This may provide the backside damage improvements discussed above. Each portion of the chuck body may be or include any of the materials described previously, and the two portions may be bonded, or otherwise formed into a monolithic component.

As described above, a power supply may be provided for each of the heater 415 and the electrode 410 in embodiments, which may be any number of power supplies. For example, the power supply for the electrode may be a DC power supply, or any other power supply, and may provide a voltage range configured to chuck a substrate to the substrate support surface 406. For example, a relatively higher power supply may be used for systems according to some embodiments of the present technology to facilitate chucking substrates having thicker deposition layers, which may be characterized by greater stress contributing to bowing. As one non-limiting example, for ON stacks, as the number of pairs of layers increases, the forces acting on the substrate may increase. Higher temperatures may contribute to these forces, further increasing the amount of bowing, and challenging the capability to properly chuck the substrate to the support assembly.

To compensate for these forces, an increased chucking voltage may be used to maintain a substantially planar substrate surface, although an amount of bowing may still occur. As these layer pairs continue to increase, the minimum voltage to maintain chucking may continue to increase. Consequently, in some embodiments a minimum chucking voltage may be above or about −250 V, and depending on the stress and number of pairs to compensate, the minimum chucking voltage may be greater than or about −300 V, greater than or about −350 V, greater than or about −400 V, greater than or about −450 V, greater than or about −500 V, greater than or about −550 V, greater than or about −600 V, greater than or about −650 V, greater than or about −700 V, greater than or about −750 V, greater than or about −800 V, greater than or about −850 V, greater than or about −900 V, greater than or about −950 V, greater than or about −1,000 V, or more.

Electrostatic chuck body 405 may also be or include materials characterized by a particular volumetric resistivity. As noted above, the chuck body may be or include a ceramic material, such as aluminum nitride, or any of the materials discussed above. In some embodiments, the materials may be selected, doped, or produced, such as sintered, to provide a volumetric resistivity above a threshold. For example, in some embodiments, the chuck body, including a one or multi-piece body as previously described, may be or include a dielectric material, such as an aluminum nitride material, characterized by a volumetric resistivity greater than or about 5×10⁸ ohm-cm at a temperature of greater than or about 550° C., greater than or about 600° C., greater than or about 650° C., or more. The chuck body may also be characterized by a volumetric resistivity greater than or about 1×10⁹ ohm-cm, greater than or about 5×10⁹ ohm-cm, greater than or about 1×10¹⁰ ohm-cm, greater than or about 3×10¹° ohm-cm, greater than or about 5×10¹⁰ ohm-cm, greater than or about 7×10¹⁰ ohm-cm, greater than or about 1×10¹¹ ohm-cm, greater than or about 3×10¹¹ ohm-cm, greater than or about 5×10¹¹ ohm-cm, greater than or about 7×10¹¹ ohm-cm, greater than or about 1×10¹² ohm-cm, or greater at any of these temperature ranges.

An effective resistivity may also be accommodated by adjusting the amount of contact between a substrate and the substrate support assembly, for example. As illustrated in FIG. 4, a number of protrusions 425 may be included or defined along the substrate support surface 406. The protrusions may provide points of contact across a planar area of a substrate support surface or the recessed pocket. Consequently, the substrate may be in contact with the substrate support assembly along a percentage of the surface area of the substrate.

A substrate 430 positioned on substrate support surface 406 may contact each of the protrusions 425, and may additionally extend at least partially across ledge 420 within recessed pocket 408. The present technology may increase the contact percentage along the wafer by increasing a number of protrusions. For example, the present technology may form protrusions characterized by a diameter or width of about 1 mm, about 2 mm, or more, and may in some embodiments include a combination of protrusions characterized by a diameter of greater than or about 1 mm and protrusions characterized by a diameter of greater than or about 2 mm. The protrusions may be characterized by any number of geometries and profiles in embodiments of the present technology. For an exemplary substrate support assembly, the substrate support surface within the recessed pocket may define greater than or about 250 protrusions, and may define greater than or about 500 protrusions, greater than or about 750 protrusions, greater than or about 1,000 protrusions, greater than or about 1,250 protrusions, greater than or about 1,500 protrusions, greater than or about 1,750 protrusions, greater than or about 2,000 protrusions, or more. The protrusions may be defined in any number of formations or patterns including uniform patterns as well as general distributions across the surface.

By producing protrusions according to some embodiments of the present technology, and by forming ceramics characterized by reduced grain sizes, a percentage of contact along a surface of a substrate may be increased to greater than or about 1.0%, and may be greater than or about 1.5%, greater than or about 2.0%, greater than or about 2.5%, greater than or about 3.0%, greater than or about 3.5%, greater than or about 4.0%, greater than or about 4.5%, greater than or about 5.0%, or greater. The percentage of contact may be maintained below or about 10% to limit leakage current below the previously stated ranges, and may limit contact below or about 8%, below or about 6%, below or about 5%, or less. Additionally, the protrusions themselves may be adjusted to affect the impact caused on substrates.

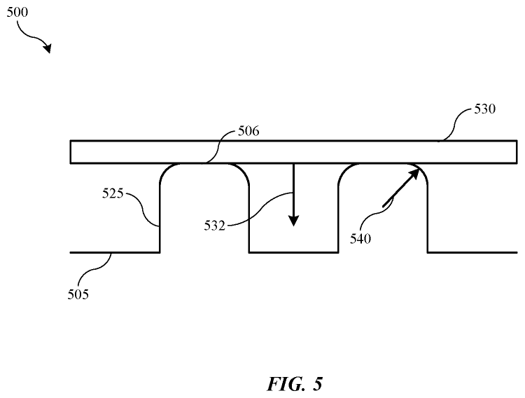

FIG. 5 shows a schematic partial cross-sectional view of an exemplary substrate support assembly 500 according to some embodiments of the present technology. Substrate support assembly 500 may include any of the materials or components previously described, and may illustrate additional details of substrate support assemblies previously discussed. As illustrated, the figure may show a detailed view of an electrostatic chuck body 505, and more specifically a substrate support surface 506, which may be configured to support a semiconductor substrate 530. The chuck body and support surface may include any characteristics as previously described for other substrate support assemblies. A number of protrusions 525 may be defined along the substrate support to provide substrate support surface 506, which may contact substrate 530 during processing.

During chucking operations, a Johnsen-Rahbek force may effect chucking where the substrate contacts the protrusions. This force, may be highest at the edges of protrusions 525 contacting the substrate. Additionally, a Coulombic force may exist in the regions between protrusions, which may pull the substrate towards the substrate support surface, as illustrated by arrow 532. Many processes may be performed at high temperatures, which may facilitate flexure of the substrate between adjacent protrusions. The protrusion formation process may provide protrusions characterized by a relatively sharp corner at the edge of the cylindrical or other geometrically-shaped feature. The interaction, in addition with the increased force at the protrusion edges, may increase scratching of the backside of the wafer causing the issues previously explained. The present technology may further adjust the protrusions to provide an amount of rounding on the edges about the protrusions. This may reduce or limit the sharp contact between the edge of a protrusion and the substrate.

By providing a rounded corner on the protrusions 525, an edge interaction with the substrate may be reduced when a substrate begins deflecting, which may reduce or limit scratching on the backside of the substrate. In some embodiments an additional polishing operation may be performed during formation of the substrate support protrusions. The substrate support may be characterized by any of the features or characteristics discussed previously, and the additional polishing operation may provide both a smoother contact surface, as well as rounded corners extending radially about each protrusion. The additional polishing may include any number of polishing operations, which may include a mechanical soft polish, a chemical polish, a laser ablation or reduction, or any other ways by which a rounded profile may be produced.

In some embodiments protrusions may be developed to a greater height acknowledging that the additional polishing operation may reduce the height of the protrusions to a target level. For example, along with providing a rounded corner, the polishing operation may reduce the height of the protrusions by less than or about 10 μm in some embodiments. Additionally, the polishing may reduce a surface roughness of the substrate support surface 506. For example, in some embodiments the average roughness across the substrate support surface of each protrusion may be less than or about 1.00 μm, and may be less than or about 0.95 μm, less than or about 0.90 μm, less than or about 0.85 μm, less than or about 0.80 μm, less than or about 0.75 μm, less than or about 0.70 μm, less than or about 0.65 μm, less than or about 0.60 μm, less than or about 0.55 μm, less than or about 0.50 μm, less than or about 0.45 μm, less than or about 0.40 μm, or less in some embodiments.

The additional polishing may produce an edge blend creating a rounded corner extending radially about the protrusion. Because the substrate may deflect about the protrusions in all directions, a consistent rounding may facilitate a reduction in edge contact between the protrusions and the substrate. The amount of rounding may vary depending on any number of characteristics of the protrusions or substrate support, although in some embodiments the corner radius, illustrated by arrow 540, may be less than or about 30% of a height of the protrusion, and may be less than or about 25% of the height, less than or about 20% of the height, less than or about 18% of the height, less than or about 15% of the height, less than or about 14% of the height, less than or about 13% of the height, less than or about 12% of the height, less than or about 11% of the height, less than or about 10% of the height, less than or about 9% of the height, or less, although in some embodiments the corner radius may be greater than or about 5% to ensure a reduced edge of the protrusions are contacting the substrate.

For example, for a 30 μm tall protrusion, the corner radius may be less than or about 10 μm, and may be less than or about 9 μm, less than or about 8 μm, less than or about 7 μm, less than or about 6 μm, less than or about 5 μm, less than or about 4 μm, less than or about 3 μm, less than or about 2 μm, or less, although in some embodiments the corner radius may be greater than or about 3 μm to ensure sufficient rounding to limit edge contact. It is to be understood that protrusions encompassed by embodiments of the present technology may be characterized by any other height or diameter as discussed previously. By providing substrate support assemblies characterized by reduced grain sizes and/or protrusions characterized by a rounded edge profile, the present technology may afford reduced backside damage on processed substrates, which may limit fall-on particles and lithography defocus, as well as improve device yield.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A substrate support assembly comprising:
an electrostatic chuck body defining a substrate support surface;
a support stem coupled with the electrostatic chuck body;
a heater embedded within the electrostatic chuck body; and
an electrode embedded within the electrostatic chuck body between the heater and the substrate support surface, wherein the substrate support assembly comprises a ceramic material characterized by a grain size of less than or about 5 μm.

2. The substrate support assembly of claim 1, wherein the electrostatic chuck body defines a recessed pocket along the substrate support surface encompassing a central region of the electrostatic chuck body.

3. The substrate support assembly of claim 2, wherein the substrate support surface defines a recessed ledge extending radially inward from an outer radial edge of the recessed pocket.

4. The substrate support assembly of claim 3, wherein the electrostatic chuck body defines a plurality of protrusions extending from the substrate support surface within the recessed pocket.

5. The substrate support assembly of claim 4, wherein each protrusion of the plurality of protrusions is characterized by a rounded corner profile characterized by a corner radius of at least 10% of a height of each protrusion.

6. The substrate support assembly of claim 4, wherein the electrostatic chuck body defines greater than or about 500 protrusions, and wherein each protrusion of the plurality of protrusions is characterized by a diameter of greater than or about 1 mm.

7. The substrate support assembly of claim 6, wherein a subset of protrusions of the plurality of protrusions are characterized by a diameter of greater than or about 2 mm.

8. The substrate support assembly of claim 4, wherein the plurality of protrusions define a contact area for a substrate seated on the substrate support surface of the electrostatic chuck body, and wherein the contact area is less than or about 10% of a planar area of the substrate.

9. The substrate support assembly of claim 1, wherein the ceramic material characterized by a grain size of between about 1 μm and about 3 μm.

10. The substrate support assembly of claim 9, wherein the ceramic material comprises aluminum nitride.

11. The substrate support assembly of claim 9, wherein the ceramic material is characterized by a surface roughness arithmetical mean height of less than or about 0.5 μm.

12. The substrate support assembly of claim 9, wherein the ceramic material is characterized by a surface roughness maximum peak height of less than or about 2 μm.

13. A substrate support assembly comprising:
a first electrostatic chuck body defining a substrate support surface;
a second electrostatic chuck body defining a bulk chuck body;
a support stem coupled with the second electrostatic chuck body;
a heater embedded within the second electrostatic chuck body; and
an electrode embedded within the second electrostatic chuck body between the heater and the first electrostatic chuck body, wherein the first electrostatic chuck body comprises a ceramic material characterized by an average grain size of less than or about 5 μm.

14. The substrate support assembly of claim 13, wherein the second electrostatic chuck body comprises a ceramic material characterized by an average grain size of greater than or about 3 μm.

15. The substrate support assembly of claim 14, wherein the first electrostatic chuck body comprises aluminum nitride, and wherein the second electrostatic chuck body comprises aluminum nitride.

16. The substrate support assembly of claim 13, wherein the first electrostatic chuck body defines a recessed pocket within the substrate support surface configured to receive a substrate for processing.

17. The substrate support assembly of claim 16, wherein the substrate support surface defines a recessed ledge extending radially inward from an outer radial edge of the recessed pocket.

18. The substrate support assembly of claim 13, wherein the first electrostatic chuck body defines a plurality of protrusions extending from the substrate support surface within the recessed pocket, and wherein the plurality of protrusions define a contact area for a substrate seated on the substrate support surface of the first electrostatic chuck body, and wherein the contact area is less than or about 5% of a planar area of the substrate.

19. The substrate support assembly of claim 13, wherein the first electrostatic chuck body is characterized by a surface roughness arithmetical mean height of less than or about 0.5 μm.

20. A method of processing a semiconductor substrate, the method comprising:
clamping a semiconductor substrate to a substrate support with a chucking voltage of greater than or about −300 V;
heating a substrate to a processing temperature causing thermal expansion of the semiconductor substrate; and
de-clamping the semiconductor substrate, wherein scratches formed on a backside of the semiconductor substrate are limited to a width of less than or about 2 μm or less.
